(19) United States
(12) Patent Application Publication
(10) Pub. No.: US 2023/0090649 A1
(43) Pub. Date: Mar. 23, 2023

(54) Radiation Detection Device and Radiographic Imaging Device Comprising Radiation Detection Device and Image Conversion Unit

(71) Applicant: Mitsubishi Chemical Corporation, Tokyo (JP)

(72) Inventors: Shigeki Hattori, Tokyo (JP); Koji Hazu, Tokyo (JP)

(73) Assignee: Mitsubishi Chemical Corporation, Tokyo (JP)

(21) Appl. No.: 18/058,375

(22) Filed: Nov. 23, 2022

Related U.S. Application Data
(63) Continuation of application No. PCT/JP2021/016089, filed on Apr. 20, 2021.

(30) Foreign Application Priority Data
May 28, 2020 (JP) 2020-093623

(51) Int. Cl. G01T 1/24

(52) U.S. Cl. CPC G01T 1/241

(57) ABSTRACT

Provided is a radiation detection device, comprising: a radiation detection unit consisting of two or more radiation detection elements each constituted by a pair of electrodes consisting of a first electrode and a second electrode and a radiation absorption layer that is sandwiched between the pair of electrodes, the two or more radiation detection elements being arranged in a surface direction of the radiation absorption layer; and one or more power supply units electrically connected to the first electrode, wherein the radiation detection unit comprises two or more of the first electrodes to which mutually different voltages are applied.

### CROSS REFERENCE TO RELATED APPLICATIONS

This application is a Continuation of PCT International Application No. PCT/JP2021/016089, filed on Apr. 20, 2021, which is claiming priority of Japanese Patent Application No. 2020-093623, filed on May 28, 2020, the entire contents of which are incorporated herein by reference.

### TECHNICAL FIELD

The present invention relates to a radiation detection device. The present invention also relates to a radiographic imaging device comprising a radiation detection device and an image conversion unit.

### BACKGROUND ART

Radiation detection is used in various fields such as security, medical care, and resource exploration. For example, by arranging radiation conversion element(s) for converting radiation into electrical signals (hereinafter simply referred to as “conversion element(s)” in some cases) in an array and by irradiating an object with radiation, an image of the object is drawn based on the dose detected by each conversion element by utilizing the fact that the dose of radiation incident on each conversion element is different when the radiation absorption differs depending on the position of the object.

The existing common methods of converting radiation into electrical signals include: a method of converting radiation into electromagnetic waves such as visible light by a scintillator and then converting the electromagnetic waves into electrical signals by a photoelectric conversion unit using a radiation detection element including the scintillator and the photoelectric conversion unit (hereinafter simply referred to as a “detection element” in some cases) (indirect conversion method); and a method of directly converting radiation into electrical signals using a conversion element such as a semiconductor (direct conversion method). Currently, the indirect conversion method is the mainstream from the viewpoint of the processing cost of the conversion element or the like. However, in the indirect conversion method, electromagnetic waves emitted by the scintillator are emitted in all directions and further scattered inside the scintillator, and thus, a so-called “crosstalk” is likely to occur, in which an electromagnetic wave emitted from a scintillator in a certain detection element is detected by a nearby detection element, and the position resolution tends to decrease.

Meanwhile, in the direct conversion method, for example, electrodes are placed on both sides of the radiation absorption layer that converts radiation into an electrical charge, and a voltage is applied between the electrodes to generate an electrical field in the radiation absorption layer, and radiation is applied such that the charge generated in the radiation absorption layer moves along the direction of the electrical field and reach the electrodes. Here, radiation is detected based on the principle that the charge accumulation in the electrodes or the resulting change in voltage between the electrodes is taken out as an electrical signal.

By guiding the charge generated in the radiation absorption layer in a specific direction in this manner, the occurrence of crosstalk can be suppressed. Therefore, the direct conversion method has better position resolution than the indirect conversion method.

A method of detecting radiation with high sensitivity using, as an example of the conversion element of the direct conversion method, an inorganic compound single crystal such as CdTe or CdZnTe for the radiation absorption layer has been reported (see Patent Documents 1 and 2).

### CITATION LIST

### Patent Document

Patent Document 1: Japanese Unexamined Patent Publication No. 2016-202901
Patent Document 2: Japanese Unexamined Patent Publication No. 2017-096798

### SUMMARY OF INVENTION

### Technical Problem

However, in the conventional methods, the dynamic range of detection sensitivity in the radiation detection element using the radiation conversion element as described above is often narrow. In such cases, it was difficult to obtain a sufficiently sharp image when areas with high and low radiation doses coexist.

In other words, it is an objective of the present invention to provide a radiation detection device having a wide dynamic range according to the direct conversion method and a radiographic imaging device.

### Solution to Problem

As a result of intensive studies in view of the above-described problems, the present inventors found that the above-described problems can be solved by obtaining a plurality of radiation detection elements having different sensitivities by a method in which mutually different voltages are applied to radiation detection elements in a radiation detection unit including a plurality of radiation detection elements, each of which is constituted by a pair of electrodes and a radiation absorption layer that is sandwiched between the pair of electrodes. This has led to the completion of the present invention.

Specifically, the present invention encompasses the following.

[1] A radiation detection device, comprising:

a radiation detection unit including two or more radiation detection elements each constituted by a pair of electrodes consisting of a first electrode and a second electrode and a radiation absorption layer that is sandwiched between the pair of electrodes, the two or more radiation detection elements being arranged in a surface direction of the radiation absorption layer; and

one or more power supply units electrically connected to the first electrode,

wherein the radiation detection unit comprises two or more of the first electrodes to which mutually different voltages are applied.

[2] The radiation detection device according to [1], wherein a value of a product μₕτₕ of a hole mobility μₕ and a hole lifetime τₕ for the radiation absorption layer is 5.0×10⁻⁴ cm²V⁻¹ or more.
[3] The radiation detection device according to [1] or [2], which comprises two or more of the first electrodes to which mutually different voltages are applied according to any of the following configurations (a) and (b):
(a) comprising two or more power supply units such that mutually different voltages are applied to two or more of the first electrodes; and
(b) comprising one or more voltage converters such that mutually different voltages are applied to two or more of the first electrodes.
[4] The radiation detection device according to any one of [1] to [3], wherein the radiation absorption layer comprises a crystal of a compound having a composition satisfying the following Formula (1):

AₓB_{y}C_{3z} (1)

(in Formula (1) above, A, B, and C represent elements that constitute the compound, A contains a cation, B contains a fourth to sixth period metal element, C contains an anion, and x, y, and z indicate molar ratios of A, B, and C, respectively, and are independently 0.5≤x≤1.5, 0.5≤y≤1.5, and 0.5≤z≤1.5).
[5] The radiation detection device according to [4], wherein the B comprises any one or more selected from Cd, In, Sn, Hg, Tl, Pb, and Bi.
[6] The radiation detection device according to [4] or [5], wherein the A comprises any one or more selected from K, Rb, and Cs.
[7] The radiation detection device according to any one of [4] to [6], wherein the C comprises any one or more selected from Cl, Br, and I.
[8] The radiation detection device according to any one of [1] to [7], wherein the radiation absorption layer has a thickness of 3 mm or less.
[9] The radiation detection device according to any one of [1] to [8], which includes:

a capacitor that is connected to an electrode element of the second electrode and secondarily accumulates a charge accumulated in the electrode element; and

an electrical signal output unit that outputs a charge accumulated in the capacitor as an electrical signal.

A radiographic imaging device comprising:

the radiation detection device according to [9]; and

an image conversion unit that converts a signal from the electrical signal output unit into an image.

### Advantageous Effects of Invention

According to the present invention, a radiation detection device having a wide dynamic range according to the direct conversion method and a radiographic imaging device can be provided.

### BRIEF DESCRIPTION OF DRAWINGS

FIG. 1 is a diagram showing an example of an electrical signal output unit included in a device according to one embodiment of the present invention.

FIG. 2 is a schematic diagram of a device according to one embodiment of the present invention.

FIG. 3 is a schematic diagram of a device according to another embodiment of the present invention.

FIG. 4 is a diagram showing an example design of a power supply unit of a device according to one embodiment of the present invention.

### DESCRIPTION OF EMBODIMENTS

A first aspect of a device according to one embodiment of the present invention may be the following radiation detection device:

a radiation detection device comprising: a radiation absorption layer having a first surface and a second surface opposite to the first surface; a first electrode disposed on the first surface; a second electrode disposed on the second surface; and one or more power supply units electrically connected to the first electrode. In addition, the first electrode includes two or more divided areas, and each area is electrically connected to one of the power supply units. The second electrode includes two or more divided electrode elements, and the electrode elements of the second electrode, together with the areas of the first electrode that is paired therewith and the radiation absorption layer, constitute a detection element.

The power supply units can apply mutually different voltages to the two or more divided areas of the first electrode. With such a configuration, it is possible to apply different voltages to a plurality of detection elements. Thus, a radiation detection device having a wide dynamic range according to the direct conversion method can be provided.

A second aspect of the device according to one embodiment of the present invention is a radiation detection device, comprising: a radiation detection unit consisting of a plurality of radiation detection elements each constituted by a pair of a first electrode and an electrode element of a second electrode and a radiation absorption layer that is sandwiched between the pair of electrodes, the two or more radiation detection elements being arranged in a surface direction of the radiation absorption layer; and one or more power supply units electrically connected to the first electrode.

In addition, in the radiation detection device, the power supply unit can apply mutually different voltages to the first electrodes of the respective detection elements in the radiation detection unit.

In a case in which the power supply unit applies mutually different voltages to the first electrodes of the respective detection elements in the radiation detection unit, the radiation detection unit comprises two or more of the first electrodes to which mutually different voltages are applied. In this case, the radiation detection device is

a radiation detection device, comprising:

a radiation detection unit consisting of two or more radiation detection elements each constituted by a pair of electrodes consisting of a first electrode and a second electrode and a radiation absorption layer that is sandwiched between the pair of electrodes, the two or more radiation detection elements being arranged in a surface direction of the radiation absorption layer; and

one or more power supply units electrically connected to the first electrode,

wherein the radiation detection unit comprises two or more of the first electrodes to which mutually different voltages are applied.

In the radiation detection device, the first electrode may be shared by a plurality of radiation detection elements.

In the first aspect of the device according to one embodiment of the present invention, it is preferable that the power supply units apply mutually different voltages to two or more divided areas of the first electrode according to any of the following methods (a) and (b):

(a) comprising two or more power supply units such that mutually different voltages are applied to two or more divided areas of the first electrode; and
(b) comprising one or more voltage converters such that mutually different voltages are applied to two or more divided areas of the first electrode.

In addition, in the second aspect of the device according to one embodiment of the present invention, it is preferable that the radiation detection device comprises two or more of the first electrodes to which mutually different voltages are applied due to any of the following configurations (a) and (b):

(a) comprising two or more power supply units such that mutually different voltages are applied to two or more of the first electrodes; and
(b) comprising one or more voltage converters such that mutually different voltages are applied to two or more of the first electrodes.

Hereinafter, the device according to one embodiment of the present invention may be referred to as a “first device.”

### <Radiation Absorption Layer>

A radiation absorption layer provided to the first device (hereinafter simply referred to as a “radiation absorption layer” in some cases) comprises a substance that generates electrical charges when exposed to energy rays such as radiation (hereinafter sometimes described as “radiation absorbing substance”). The radiation absorbing substance may be used singly or two or more thereof may be used in combination, or it may be used in combination with other substances. An aspect of the combination of two or more radiation absorbing substances or the combination of a radiation absorbing substance with other substances is not particularly limited. For example, they may be layered in the thickness direction connecting the first electrode and the second electrode or may be arranged side by side in the surface direction perpendicular to the thickness direction.

Examples of radiation include a-rays, y-rays, X-rays, and neutron rays. X-rays or y-rays are preferable from the viewpoint of utilization in the medical and security fields, and X-rays are preferable from the viewpoint of versatility in application fields.

The charges to be detected are electrons or positive holes.

It is preferable that the bandgap of the radiation absorbing substance is as large as possible within the range not exceeding the energy of the radiation. In addition, the lower limit of the range in which the applied voltage does not become more than necessary is usually 1.25 eV or more, preferably 1.5 eV or more, more preferably 2.0 eV or more, still more preferably 2.2 eV or more, and particularly preferably 5 eV or more. The upper limit thereof is usually 100 keV or less, preferably 80 keV or less, and more preferably 60 keV or less. As long as the bandgap is not less than the lower limit of the above-described range, it is possible to reduce the frequency of generation of heat carriers and reduce the noise of electrical signals generated independently of radiation exposure. In addition, as long as the bandgap is not more than the upper limit of the above-described range, the energy of incident radiation can be efficiently absorbed, and the generated charge can be efficiently transferred to the electrode, and thus, the detection sensitivity can be increased.

The electrical resistance of the radiation absorbing substance is usually 10⁴ Ωcm or more, preferably 10⁶ Ωcm or more, and still more preferably 10⁸ Ωcm or more. As long as the electrical resistance is not less than the lower limit of the above-described range, current leakage can be reduced, and a high signal/noise (S/N) ratio can be obtained. The upper limit thereof is not particularly limited, but the higher the electrical resistance, the more the insulating properties are exhibited when the radiation absorbing substance is not excited by radiation, which is preferable.

The density of the radiation absorbing substance is usually 2.0 g/cm³ or more, preferably 3.0 g/cm³ or more, and more preferably 4.0 g/cm³ or more. The upper limit thereof is not particularly limited, and the higher, the better, while the density is usually 10 g/cm³ or less. As long as the density is not less than the lower limit of the above-described range, radiation absorption efficiency increases, and thus, a high radiation detection sensitivity can be obtained with the radiation detection device.

The effective atomic number (Z_{eff}) of the radiation absorbing substance is usually 40 or more, preferably 50 or more, more preferably 55 or more, and still more preferably 60 or more. The upper limit thereof is not particularly limited, but the higher, the better, while the effective atomic number is usually 100 or less. As long as the density is not less than the lower limit of the above-described range, radiation absorption efficiency increases, and thus, a high radiation detection sensitivity can be obtained with the radiation detection device. The effective atomic number (Z_{eff}) can be determined based on the composition of the radiation absorbing substance with reference to the description of Medical Physics, 39(2012), pp. 1769-1778.

The product μₕτₕ, of the hole mobility μₕ and the hole lifetime τₕ for the radiation absorbing substance is usually 1.0×10⁻⁷ cm²V⁻¹ or more, preferably 1.0×10⁻³ cm²V⁻¹ or more, more preferably 1.0×10⁻⁴ cm²V⁻¹ or more, still more preferably 3.0×10⁻⁴ cm²V⁻¹ or more, even more preferably 5.0×10⁻⁴ cm²V⁻¹ or more, and particularly 1.0×10⁻³ cm²V⁻¹ or more. The upper limit of the product is not particularly limited, and the higher, the better, while the product is usually 1.0×10⁻¹ cm²V⁻¹ or less.

Examples of a substance for which the product μₕτₕ of the hole mobility μₕ and the hole lifetime τₕ is within an appropriate range of, for example, 1.0×10⁻³ cm²V⁻¹ or more include compounds represented by the formula (1) described later such as amorphous silicon (a-Si, 9.6×10⁻³ cm²V⁻¹), amorphous selenium (a-Se, 6×10⁻³ cm²V⁻¹), CdTe (2.3×10⁻⁴ cm²V⁻¹), HgI₂ (4×10⁻³ cm²V⁻¹), and CsPbBr₃ (1.3×10⁻³ cm²V⁻¹).

Further, as long as the product is not less than the lower limit of the above-described range, a high positive hole detection sensitivity can be obtained. In addition, as long as the product is 5.0×10⁻⁴ cm²V⁻¹ or more, the effect of adjusting the radiation detection sensitivity depending on the voltage applied is likely to be obtained, which is preferable. The product μₕτₕ, of the hole mobility and the hole lifetime can be determined from the relational expression obtained by carrying out photoconductivity measurement involving current-voltage measurement with photoexcitation (see Journal of Physics of and Chemistry of Solids 1965, Vol. 26, pp. 575-578).

The product μₑτₑ of the electron mobility μₑ and the electron lifetime τₑ for the radiation absorbing substance is usually 1.0×10⁻⁷ cm²V⁻¹ or more, preferably 1.0×10⁻³ cm²V⁻¹ or more, more preferably 1.0×10⁻⁴ cm²V⁻¹ or more, still more preferably 3.0×10-4 cm²V⁻¹ or more, even more preferably 5.0×10⁻⁴ cm²V⁻¹ or more, and particularly 1.0×10⁻³ cm²V⁻¹ or more as in the case of the positive hole. The upper limit of the product is not particularly limited, and the higher, the better, while the product is usually 1.0×10⁻¹ cm²V⁻¹ or less. The product μₑτₑ of the electron mobility and the electron lifetime can be determined by the same method as with the positive hole (see the literature above).

From the viewpoint of uniformity of sensitivity, the radiation absorbing substance is preferably crystalline, more preferably a single crystal. The fewer the defects, the less the possibility that radiation-induced charges are trapped, scattered, or absorbed, resulting in improved radiation absorption efficiency.

The shape of the radiation absorption layer is not particularly limited as long as it has a first surface and a second surface opposite to the first surface unless it impairs the essence of the present invention. However, it is preferable that the strength of the electrical field generated when a voltage is applied between the electrodes that are in contact with the first surface and the second surface, respectively, is even in the radiation absorption layer. In view of this, it is preferable that the distance between the first surface and the second surface is the same in at least an area where the first electrode and the second electrode are in contact therewith, which means that the first surface and the second surface are parallel surfaces. In addition, the shapes of the first surface and the second surface are not particularly limited and may be plane or curved. For examples, they may be tetragons such as square and rectangle, circles, polygons, or spheres. The shapes are preferably plane and more preferably tetragonal from the viewpoint of the ease in producing the device. Further, the radiation absorption layer may be a single layer in which a plurality of electrodes are arranged in the surface direction or a single layer in which only one pair of electrodes are arranged, In the latter case, a plurality of radiation absorption layers may be arranged in the surface direction. In another aspect, the radiation absorption layer may be a single layer formed by a plurality of detection elements conjugated to each other, or may be an independent layer for each detection element.

The surface areas of the first surface and second surfaces of the radiation absorption layer are each independently usually 1 mm² or more, preferably 4 mm² or more, and more preferably 16 mm² or more. Although the upper limit thereof is not particularly limited, it is usually 1000 mm² or less from the viewpoint of the difficulty in production. As long as the surface areas are not less than the lower limit of the above-described range, it is possible to obtain an image of a wider area in a single imaging.

In addition, the thickness of the radiation absorption layer is usually 5 mm or less, preferably 3 mm or less, more preferably 2 mm or less, still more preferably 1.5 mm or less, even more preferably 1 mm or less, particularly preferably 0.7 mm or less, and most preferably 0.5 mm or less. The lower limit thereof is not particularly limited, and the thinner the better, while the thickness of the radiation absorption layer is usually 0.1 mm or more.

As long as the thickness is not more than the upper limit of the above-described range, an appropriate position resolution can be obtained. In addition, the thinner the thickness, the easier it is for carriers to reach the electrode without deactivation such that high radiation sensitivity can be obtained. Further, as long as the thickness is not less than the lower limit of the above-described range, radiation absorption efficiency can be improved.

In one embodiment, it is preferable that the radiation absorbing substance comprises a compound represented by the following Formula (1):

AₓB_{y}C_{3z} (1)

(in Formula (1) above, A, B, and C refer to elements that constitute the compound, A contains a monovalent cation, B contains one or more selected from fourth to sixth period metal elements, C contains an anion, and x, y, and z indicate molar ratios of A, B, and C, respectively, and are independently 0.5≤x≤1.5, 0.5≤y≤1.5, and 0.5≤z≤1.5).

A above includes a monovalent cation, preferably a metal element. In consideration of the radiation absorptance, preferably one or more selected from fourth to sixth period metal elements are contained, more preferably one or more of K, Rb, and Cs are contained, and still more preferably Cs is contained.

The proportion of the cation in A is usually 50% by mole or more, preferably 70% by mole or more, still more preferably 80% by mole or more, and particularly preferably 90% by mole, or may be 100% without particular restrictions on the upper limit thereof.

B above contains one or more metal elements selected from fourth to sixth period metal elements. In consideration of the radiation absorptance and crystal structure stabilization, preferably one or more selected from fifth and sixth period metal elements are contained, more preferably one or more selected from sixth period metal elements are contained, still more preferably one or more selected from Cd, In, Sn, Hg, Tl, Pb, and Bi are contained, even more preferably one or more selected from Sn, Pb, and Bi are contained, and particularly preferably Pb is contained.

The proportion of the one or more metal elements selected from fourth to sixth period metal elements in B is usually 50% by mole or more, preferably 70% by mole or more, still more preferably 80% by mole or more, and particularly preferably 90% by mole, or may be 100% without particular restrictions on the upper limit thereof.

C above contains an anion. C contains preferably a halogen anion, more preferably any one or more of Cl, Br, and I, and from the viewpoint of hole mobility improvement and crystal structure stability, sill more preferably Br.

The proportion of the anion in C is usually 50% by mole or more, preferably 70% by mole or more, still more preferably 80% by mole or more, and particularly preferably 90% by mole, or may be 100% without particular restrictions on the upper limit thereof.

In the above, x, y, and z indicate the terms in the molar ratio of A:B:C in the compound, respectively, and independently usually 0.5 or more, preferably 0.7 or more, more preferably 0.8 or more, and still more preferably 0.9 or more, and at the same time, usually 1.5 or less, preferably 1.3 or less, more preferably 1.2 or less, and still more preferably 1.1 or less.

Within the above-described range, the structure is stabilized, and a radiation absorption layer of uniform quality can be obtained.

### <Electrode>

There are no particular restrictions on the materials of the first electrode and the second electrode provided in the first device. In general, a highly conductive metal can be used. For example, Al, W, Ru, Ni, Pd, Cu, Ag, Au, Pt, Pb, Bi, and the like can be used. It is preferable that the electrodes have a characteristic of preferably a low diffusion coefficient from the viewpoint of preventing diffusion into the adjacent radiation absorption layer. For example, Al, W, Ru, Ni, Pd, Cu, Au, Pt, Pb, and Bi can be used.

The work functions of the electrodes are preferably deeper than the work function of the conduction band of the radiation absorption layer from the viewpoint of obtaining favorable electrical resistivity with high resistance and preferably shallower than the work function of the valence band of the radiation absorption layer. It should be noted that the work function is expressed as a negative value, and its essence is the minimum amount of energy required to move an electron to infinity from the surface of a substance, and the greater the energy, the greater the negative value. In this regard, when the required minimum energy is large and the negative value is large, it is expressed herein that the “work function is deep” relatively, and on the contrary, when the negative value is small, it is expressed herein that the “work function is shallow” relatively.

When charges are generated by radiation, it is preferable that either electrons or positive holes reach the first electrode and the second electrode due to the electrical field. It is optionally determined which electrode electrons and positive holes reach. However, a case in which positive holes reach the first electrode and electrons reach the second electrode and are detected will be described below.

In this case, it is preferable to apply a negative voltage to the first electrode.

In the case of applying a negative voltage to the first electrode, from the viewpoint that positive holes are more likely to reach the second electrode than the first electrode, it is preferable that the work function of the first electrode is shallower than the work function of the second electrode. For example, in the Examples, the first electrode is Bi and the second electrode is Au.

On the other hand, in the case of selecting a design in which electrons reach the first electrode, it is preferable to apply a positive voltage to the first electrode, and it is also preferable that the work function of the first electrode is deeper than the work function of the second electrode. For example, the first electrode can be Au and the second electrode can be Bi.

In a case in which positive holes reach the first electrode, it is preferable in that it is easier to obtain the effect of adjusting the radiation detection sensitivity by the applied voltage.

In the first aspect of the first device, the first electrode is in contact with the first surface of the radiation absorption layer and divided into two or more areas. Each of the divided areas of the first electrode may be connected to different power supply units, which will be described later. In addition, each of the divided areas of the first electrode can be paired with one or more of the second electrodes, which will be described later, thereby forming a detection element. From another viewpoint, in the radiation detection unit, the first electrode may be connected between a plurality of detection elements, or may be independent for each detection element.

The above-described structure allows the voltage that is applied between the first electrode and the second electrode to have two or more different voltage values independently for each area corresponding to the electrode element of the second electrode described later, i.e., for each detection element.

In the second aspect of the first device, the first electrode is in contact with the first surface of the radiation absorption layer. The first electrode may be connected to a different power supply unit, which will be described later, for each detection element. In addition, the first electrode can be paired with one or more of the second electrodes, which will be described later, thereby forming a detection element. From another viewpoint, in the radiation detection unit, the first electrode may be connected between a plurality of detection elements, or may be independent for each detection element.

The above-described structure allows the voltage that is applied between the first electrode and the second electrode to have two or more different voltage values for each detection element corresponding to the electrode element of the second electrode described later.

The second electrode is in contact with the second surface of the radiation absorption layer, and may be arranged in an array of two or more pixels. The shape of each pixel is not particularly limited, and may be square, circular, triangular, or the like. In addition, the surface area of a pixel is usually about from 10 μm² to 1000 μm². As long as the surface area is within the above-described range, a suitable spatial resolution can be obtained.

### <Power Supply Unit>

The power supply unit may be connected to one or more areas of the first electrode so as to apply a voltage to each area of the first electrode. Alternatively, the power supply unit may be connected to one or more first electrodes so as to apply a voltage to the first electrodes. The power supply unit may be connected to an external power supply when used for supplying electrical power to the first electrode or may include a built-in power supply so as to independently supply electrical power to the first electrode. A commonly used power supply can be used for the external power supply or a built-in power supply. For example, a direct current (DC) power supply or an alternating current (AC) power supply can be used.

It is preferable for a plurality of areas of a first electrode, or two or more first electrodes used for radiation detection that all areas or the electrodes are connected to the power supply unit from the viewpoint that power is applied by the power supply.

### <Voltage Converter>

The power supply unit may comprise a voltage converter for the purpose of applying different voltages to a plurality of areas of the first electrode or two or more of the first electrodes. The arrangement of the voltage converter is not particularly limited as long as the purpose is achieved. Usually, the voltage converter is arranged between a power supply and a first electrode. For example, a voltage converter may be connected directly or via a certain circuit to a power supply. A known voltage converter can be used. For example, a linear regulator or a switching regulator can be used. By providing a voltage converter as described above, it is possible to apply different voltage values to each area of a first electrode or a first electrode of each detection element, thereby obtaining a device comprising electrode elements having mutually different radiation detection sensitivities. A voltage converter may be used singly or provided to each of a plurality of power supply units.

### <Electrical Signal Output Unit>

The first device may comprise an electrical signal output unit. The electrical signal output unit is connected to any electrode element of the second electrode and outputs the charges accumulated in the electrode element as an electrical signal. The electrical signal output unit may be provided inside of the first device, or an external electrical signal output device may be used. It is preferable that one electrical signal output unit is provided to each electrode element of the second electrode, and each electrical signal output unit is connected to the corresponding second electrode element.

The electrical signal output unit comprises at least one or more charge accumulation circuits which secondarily accumulates the charges accumulated in the second electrode element and an electrical signal output circuit which outputs the charges accumulated in the charge accumulation circuit as an electrical signal. For example, a capacitor can be used as a charge accumulation circuit.

As the operation of the electrical signal output circuit, it is preferable to enable at least one of the following operations, and a circuit capable of realizing these operations can be used: outputting an electrical signal based on charges when the charges accumulated in one of the charge accumulation units reaches a threshold value or more; outputting the charges accumulated in one of the capacitors as an electrical signal at regular intervals; and outputting the charges accumulated in one of the capacitors as an electrical signal by the operation of external power (for example, using a transistor switch or the like). These operations may be performed singly or in combination. In addition, some or all of the circuits corresponding to these operations may be provided in plurality, and may have a repetitive structure. By the above operation, the charges accumulated in each pixel of the second electrode can be output as an electrical signal at each constant threshold value and/or at regular intervals.

Further, the electrical signal output unit may comprise an amplifier circuit that amplifies a charge or electrical signal information (e.g., an amplifier or integration amplifier circuit), a glitch elimination circuit such as a sample-and-hold circuit, a grounding wire that can be connected to a circuit that can accumulate electrical charges and a switch that switches ON/OFF of the connection between the grounding wire and the circuit, a filter circuit (e.g., a low-pass filter or high-pass filter) that removes unwanted low-frequency and high-frequency noise, and the like. By appropriately providing these circuits, it is possible to improve the sensitivity, remove noise, remove residual charges after the output of the electrical signal, and improve the accuracy of the electrical signal.

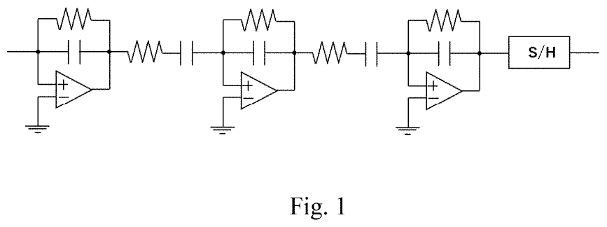

FIG. 1 exemplifies an electrical signal output unit according to one embodiment. FIG. 1 is an example in which an electrical signal output unit for outputting a signal sent to a charge detection amplifier is composed of integration amplifier circuits in a three-stage setting and a sample-and-hold (S/H) circuit. By providing the electrical signal output unit as described above, it is possible to obtain an electrical signal having information on energy and time while eliminating noise.

A sampled-and-held signal is passed through an analog-to-digital (A/D) converter as a digital signal to be constructed as an image in a subsequent image conversion unit.

The structure of the electrical signal output unit is not limited to FIG. 1. A common circuit capable of achieving the desired purpose can be used, and appropriate circuits can be combined according to the purpose.

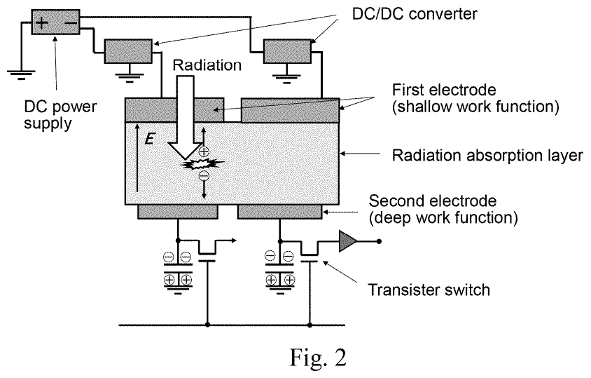

FIG. 2 exemplifies a schematic diagram of a device in one embodiment of the present invention. Radiation is applied to a radiation absorption layer, electrons and positive holes are generated in the radiation absorption layer, and a predetermined negative voltage is applied to a first electrode from a direct current (DC) power supply through a direct-current voltage converter (DC/DC converter). As a result, an electrical field (E) is applied to the radiation absorption layer, and the generated positive holes move to the first electrode and the electrons move to a second electrode. The transferred electrons are accumulated in a capacitor. A voltage is applied to the gate of a transistor switch to turn it on such that a current signal is passed through the signal line, the signal is sent to the charge detection amplifier and outputted as an encoded digital signal through an image conversion unit, thereby creating a 2D image. For simplicity, FIG. 2 shows a case in which there are two first electrodes and two second electrodes. There may be three or more first electrodes, or the second electrodes may outnumber the first electrodes and may be arranged in an array of electrode elements in an actual setting.

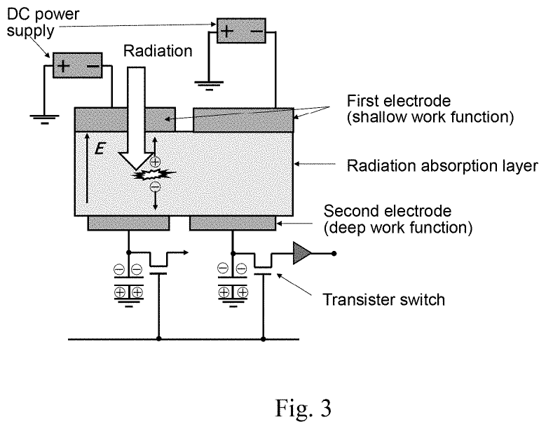

FIG. 3 exemplifies a schematic diagram of a first device in another embodiment of the present invention. In this example, the basic principle is the same as the device exemplified in FIG. 2. However, it is possible to obtain a device comprising detection elements having mutually different radiation detection sensitivities by using two or more power supplies capable of applying mutually different voltages and connecting each area of a first electrode to one of the power supplies. Although FIG. 3 exemplifies the case where two DC power supplies are provided to generate two voltage values, there may be three or more power supplies, and also there may be three or more areas of the first electrode or three or more electrode elements of the second electrode as in the case of FIG. 2. Further, one area of the first electrode may correspond to a plurality of electrode elements of the second electrode. The first electrode may be divided while being aligned for electrode elements of the second electrode, and a plurality of voltage values may be applied respectively to the separated first electrodes. From the point of view of the second aspect of the first device, the area can be considered an independent first electrode.

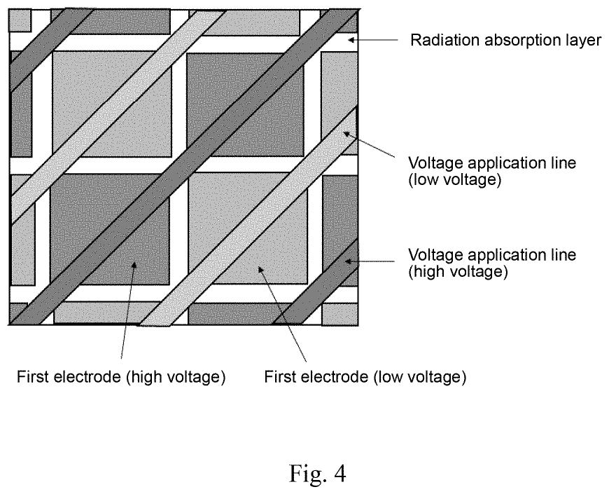

FIG. 4 shows an example of the structure of a power supply unit when two different first electrodes are used and two different voltages, which are a high voltage and a low voltage, are respectively applied thereto. FIG. 4 exemplifies a structure in which first electrodes to which a high voltage is applied and first electrodes to which a low voltage is applied are alternately arranged, and a voltage application line for applying a high voltage and a voltage application line for applying a low voltage are arranged diagonally with respect to a data line and a gate line. By adopting such a structure, the process can be simplified. In FIG. 4, first electrodes to which a high voltage is applied and first electrodes to which a low voltage is applied are arranged at a ratio of 1:1. However, the ratio between the first electrodes to which a high voltage is applied and the first electrodes to which a low voltage is applied may vary. The ratio may be adjusted optionally to, for example, 3:1 or 5:1 according to the purpose. In the case of seeking a high resolution, in order to increase the proportion of highly sensitive detection elements, it is preferable to increase the proportion of the first electrodes to which a high voltage is applied.

In addition, the voltage value applied to a first electrode may be a fixed voltage preset by a DC power supply. Meanwhile, the voltage value may be applied at a variable value that is set with a DC power supply to which a signal is sent such that when the value output to the charge detection amplifier is fed back and its average value exceeds a given value, the average value is lowered to the given value or less.

In a layered product comprising a radiation absorption layer, a first electrode, and a second electrode, one area bounded by electrode elements of the second electrode can be regarded as one detection element. In this case, the first device can independently control the applied voltage for each of the detection elements. Thus, it is possible to provide a radiation detection device that is provided with high-sensitivity detection elements and low-sensitivity detection elements based on the principle that the sensitivity of each detection element varies depending on the applied voltage, thereby having a wide dynamic range. From another viewpoint, there is no need to change the material and structure for each detection element to produce detection elements having different sensitivities in producing a radiation detection device, and thus, only the structure of the power supply unit needs to be changed. Accordingly, it is possible to provide a radiation detection device which can be structurally simplified and can be efficiently produced, and for which the sensitivity of each detection element can be easily designed.

In addition, the first device is an assembly of detection elements including two or more detection elements for which different voltages are applied, which can also be used as a radiation detection device for one picture element (pixel) for obtaining one piece of position information. Thus, the first device can be used as a sensor or the like that detects radiation at only one point when combined with a device that visualizes signal values.

The first device may also be used as a pixel-array radiation detection device in which a plurality of pixels are arranged. By using the first device in such a way, information derived from high-sensitivity and low-sensitivity detection elements can be obtained at the same position. Accordingly, a radiation detection device having a wide dynamic range at all positions can be obtained.

### <Image Conversion Unit>

Another embodiment of the present invention is a device comprising the first device and further comprising an image conversion unit. Hereinafter, the device may be referred to as a “second device.”

The image conversion unit creates image data based on the electrical signals output from the electrical signal output unit of the first device. In other words, the image conversion unit starts data collection of the signal values of the electrical signals, acquires energy values from the signal values of the electrical signals, and acquires position information from the positions of the electrode elements. Time information can also be obtained from the transmitted timings. By integrating the radiation energy values for each position, an image corresponding to the radiation absorptance of a subject in the radiation incident direction for each position is constructed. The image signal output control method is not particularly limited, and for example, conventional methods used in CMOS image sensors, CCD image sensors, and the like can be used.

Since the image conversion unit processes information of electrical signals, it is usually referred to as a signal processing unit or an information processing unit in some cases.

In a case in which first electrodes to which two or more different voltages are applied electrode are arranged in a mixed manner, images with different sensitivities are obtained according to the applied voltages, and the images with different sensitivities are combined in the image conversion unit. Usually, a blurry image due to saturated signal values obtained by using only high-sensitivity detection elements can be made clear by synthesized with non-saturated signal values of low-sensitivity detection elements. When combining images with different sensitivities, the different images may simply be integrated and combined, or arithmetic processing may be performed by referring to the saturated value of a detection element having a high sensitivity for the value of the image signal for each pixel and adopting the value of a low-sensitivity detection element, instead of the value of a high-sensitivity detection element, for the image signal value of pixel reaching the saturated value.

The second device may comprise an A/D converter between the electrical signal output unit and the image conversion unit. In a case in which the image conversion unit processes digital signals, the electrical signals can be appropriately processed by performing A/D conversion.

The device is configured such that an electrical signal derived from a low-sensitivity detection element is adopted in an area with a high radiation dose, and an electrical signal derived from a high-sensitivity detection element is adopted in an area with a low radiation dose. Accordingly, a radiation detection device and a radiographic imaging device for obtaining high-resolution images over a wide radiation dose range can be provided.

The device according to the present invention can also be used per se as a radiation detection device or may be used for an apparatus that detects radiation at spots such as an air dosimeter. The device can be used in a variety of applications, such as baggage inspection apparatuses, medical radiographic imaging apparatuses, and radiation detection apparatuses for resource searching.

What is claimed is:

1. A radiation detection device, comprising:
a radiation detection unit including two or more radiation detection elements each constituted by a pair of electrodes consisting of a first electrode and a second electrode and a radiation absorption layer that is sandwiched between the pair of electrodes, the two or more radiation detection elements being arranged in a surface direction of the radiation absorption layer; and
one or more power supply units electrically connected to the first electrode,
wherein the radiation detection unit comprises two or more of the first electrodes to which mutually different voltages are applied.

2. The radiation detection device according to claim 1, wherein a value of a product μₕτₕ of a hole mobility μₕ and a hole lifetime τₕ for the radiation absorption layer is 5.0×10⁻⁴ cm²V⁻¹ or more.

3. The radiation detection device according to claim 1, which comprises two or more of the first electrodes to which mutually different voltages are applied according to any of the following configurations (a) and (b):
(a) comprising two or more power supply units such that mutually different voltages are applied to two or more of the first electrodes; and
(b) comprising one or more voltage converters such that mutually different voltages are applied to two or more of the first electrodes.

4. The radiation detection device according to claim 1, wherein the radiation absorption layer comprises a crystal of a compound having a composition satisfying the following Formula (1):
AₓB_{y}C_{3z} (1)
(in Formula (1) above, A, B, and C represent elements that constitute the compound, A contains a cation, B contains a fourth to sixth period metal element, C contains an anion, and x, y, and z indicate molar ratios of A, B, and C, respectively, and are independently 0.5≤x≤1.5, 0.5≤y≤1.5, and 0.5≤z≤1.5).

5. The radiation detection device according to claim 4, wherein the B comprises any one or more selected from Cd, In, Sn, Hg, Tl, Pb, and Bi.

6. The radiation detection device according to claim 4, wherein the A comprises any one or more selected from K, Rb, and Cs.

7. The radiation detection device according to claim 4, wherein the C comprises any one or more selected from Cl, Br, and I.

8. The radiation detection device according to claim 1, wherein the radiation absorption layer has a thickness of 3 mm or less.

9. The radiation detection device according to claim 1, which includes:
a capacitor that is connected to an electrode element of the second electrode and secondarily accumulates a charge accumulated in the electrode element; and
an electrical signal output unit that outputs a charge accumulated in the capacitor as an electrical signal.

10. A radiographic imaging device comprising:
the radiation detection device according to claim 9; and
an image conversion unit that converts a signal from the electrical signal output unit into an image.
